(19) United States
(12) Patent Application Publication
(10) Pub. No.: US 2025/0069955 A1
(43) Pub. Date: Feb. 27, 2025

(54) Method and System for Analyzing Wafer Angle in Semiconductor Integrated Circuit Manufacturing

(71) Applicant: Shanghai Huali Microelectronics Corporation, Shanghai (CN)

(72) Inventor: Ying Cui, Shanghai (CN)

(73) Assignee: Shanghai Huali Microelectronics Corporation, Shanghai (CN)

(21) Appl. No.: 18/368,137

(22) Filed: Sep. 14, 2023

(30) Foreign Application Priority Data
Aug. 25, 2023 (CN) 202311085591.2

(51) Int. Cl. H01L 21/66; H01L 21/67

(52) U.S. Cl. CPC H01L 22/12; H01L 21/67288

(57) ABSTRACT

This application discloses a method for analyzing a wafer angle in semiconductor integrated circuit manufacturing, including step 1: collecting machine angle data; step 2: predicting and forming an angle trajectory map of each analyzed wafer in a process according to the machine angle data; step 3: performing first grouping on defective wafers in an analyzed lot according to defect types; step 4: selecting one first group as a selected group, and performing second grouping on each defective wafer in the selected group according to defect directions; and step 5: calculating a direction difference between defect directions of second groups, and determining a site and a machine where a defect occurs in combination with the direction difference and an angle difference in the angle trajectory map of each detective wafer in the selected group. This application further discloses a system for analyzing a wafer angle in semiconductor integrated circuit manufacturing.

### CROSS-REFERENCE TO RELATED APPLICATIONS

This application claims the priority to Chinese patent application No. 202311085591.2, filed on Aug. 25, 2023, the disclosure of which is incorporated herein by reference in entirety.

### TECHNICAL FIELD

This application relates to the field of semiconductor integrated circuit manufacturing, in particular to a method for analyzing a wafer angle in semiconductor integrated circuit manufacturing. This application further relates to a system for analyzing a wafer angle in semiconductor integrated circuit manufacturing.

### BACKGROUND

In the process of semiconductor chip manufacturing, due to the complexity of the process and the variety of processes, there are many types of process machines required.

The existing method for analyzing a wafer angle in semiconductor integrated circuit manufacturing adopts manual analysis, including the following steps:

In step 1, a problem occurs in a production line. The problem is mainly detected through detection equipment. Visual classification is performed manually on defects on defective wafers in a lot corresponding to the problem. The defects of the same type originate from the same source.

In step 2, machines in which the problem possibly occurs in a process loop are suspected manually based on experience according to the defects such as defect directions on the defective wafers. For example, 10 machines are listed.

In step 3, relevant angle data of the 10 listed machines are investigated manually one by one to identify suspected machines. The relevant angle data of the machine includes machine alignment angle, angle associated with loadport, angle associated with recipe, angle associated with airlock chamber, angle associated with product, and angle associated with process ID. So, according to the association, each machine usually has multiple angles, such as angle 1, angle 2, and angle 3, which are independently valued. In the existing method, it is required to manually investigate the relevant angle data one by one, resulting in a relatively large workload.

Therefore, in the existing method, in order to screen for changes of the machine angle of the production line in the process after defects occur, it is required to determine possible sites based on experience and check the angle information of each machine. As human investigation time progresses, the risk index of the production line increases, which may lead to more serious production line accidents.

### BRIEF SUMMARY

According to some embodiments in this application, a method for analyzing the wafer angle in semiconductor integrated circuit manufacturing is disclosed in the following steps:
step 1: collecting machine angle data of each machine on a production line of semiconductor integrated circuits, a machine angle being a wafer angle at which a wafer is processed on the machine;
step 2: predicting and forming an angle trajectory map of each analyzed wafer in an analyzed lot in a process according to the machine angle data, the angle trajectory map being a wafer angle distribution map of the analyzed wafer on the machine corresponding to each site in the process;
step 3: making defective wafers be the analyzed wafers with defects, and performing first grouping on the defective wafers in the analyzed lot according to defect types, the defective wafers with the same defect type being classified into the same first group in the first grouping;
step 4: selecting one first group in the first grouping as a selected group, and performing second grouping on each defective wafer in the selected group according to defect directions, the defective wafers with the same defect direction in the selected group being classified into the same second group in the second grouping; and
step 5: calculating a direction difference between the defect directions of the second groups, and determining the site and the machine where the defect on each defective wafer in the selected group occurs in combination with the direction difference and an angle difference in the angle trajectory map of each detective wafer in the selected group.

In some cases, in step 1, the machine angle data further includes a data type of the machine angle, the data type is defined by a part associated with the machine angle, and the part associated with the machine angle includes wafer loadport, wafer loadlock chamber, airlock chamber, or process chamber.

In some cases, in the data type, the part associated with the machine angle further includes recipe, product or process ID.

In some cases, the machine angle data further includes a rule judgment given according to the data type, and the rule judgment given to the same data type is the same.

In some cases, in step 1, the machine angle data is automatically collected or manually input.

In some cases, the defects on the defective wafers are obtained through test equipment.

In some cases, in step 3, in a case that the number of the first group is more than two, step 4 and step 5 are repeated to sequentially determine the site and the machine where the defect corresponding to each first group occurs.

In some cases, in step 2, the angle trajectory map includes the following changes of the wafer angle: 1 dynamically changing up-down inheritance;
fixed change;
regular angle increase or decrease;
mirrored change;
diagonal change.

In order to solve the technical problem, the system for analyzing the wafer angle in semiconductor integrated circuit manufacturing provided in this application includes:
a machine angle data collection module configured to collect machine angle data of each machine on a production line of semiconductor integrated circuits, a machine angle being a wafer angle at which a wafer is processed on the machine;
an angle trajectory map prediction module configured to predict and form an angle trajectory map of each analyzed wafer in an analyzed lot in a process according to the machine angle data, the angle trajectory map being a wafer angle distribution map of the analyzed wafer on the machine corresponding to each site in the process;
a first defect grouping module configured to make defective wafers be the analyzed wafers with defects, and perform first grouping on the defective wafers in the analyzed lot according to defect types, the defective wafers with the same defect type being classified into the same first group in the first grouping;
a second defect grouping module configured to select one first group in the first grouping as a selected group, and perform second grouping on each defective wafer in the selected group according to defect directions, the defective wafers with the same defect direction in the selected group being classified into the same second group in the second grouping; and
a comprehensive analysis module configured to calculate a direction difference between the defect directions of the second groups, and determine the site and the machine where the defect on each defective wafer in the selected group occurs in combination with the direction difference and an angle difference in the angle trajectory map of each detective wafer in the selected group.

In some cases, the machine angle data further includes a data type of the machine angle, the data type is defined by a part associated with the machine angle, and the part associated with the machine angle includes wafer loadport, wafer loadlock chamber, airlock chamber, or process chamber.

In some cases, in the data type, the part associated with the machine angle further includes recipe, product or process ID.

In some cases, the machine angle data further includes a rule judgment given according to the data type, and the rule judgment given to the same data type is the same.

In some cases, the machine angle data is automatically collected or manually input.

In some cases, the defects on the defective wafers are obtained through test equipment.

In some cases, the angle trajectory map includes the following changes of the wafer angle:
dynamically changing up-down inheritance;
fixed change;
regular angle increase or decrease;
mirrored change;
diagonal change.

In this application, machine angle data of each machine on a production line is collected in advance, then an angle trajectory of each corresponding analyzed wafer is predicted based on the machine angle data, then first grouping is performed on defective wafers according to defect types, second grouping is performed on one selected first group with the same defect type to obtain second groups, a direction difference between the defect directions of the second groups is determined, the wafer angle of the defective wafer in each second group at the time that the defect occurs can be analyzed and obtained in combination with the direction difference and an angle difference obtained from the predicted angle trajectory map, and the site and the machine where the defect occurs can be determined according to the wafer angle. Therefore, the wafer angle analysis in this application can be automatically realized without requiring for manual analysis, thus greatly improving analysis efficiency and accuracy, and reducing manpower and time consumption.

### BRIEF DESCRIPTION OF THE DRAWINGS

This application will be further described in detail below in combination with the specific embodiments with reference to the drawings.

FIG. 1 illustrates a flowchart of a method for analyzing a wafer angle in semiconductor integrated circuit manufacturing according to an embodiment of this application.

FIG. 2A to FIG. 2C illustrate schematic diagrams of defect directions of second groups in second grouping in a method for analyzing a wafer angle in semiconductor integrated circuit manufacturing according to an embodiment of this application.

FIG. 3 illustrates a structural schematic diagram of a system for analyzing a wafer angle in semiconductor integrated circuit manufacturing according to an embodiment of this application.

### DETAILED DESCRIPTION OF THE APPLICATION

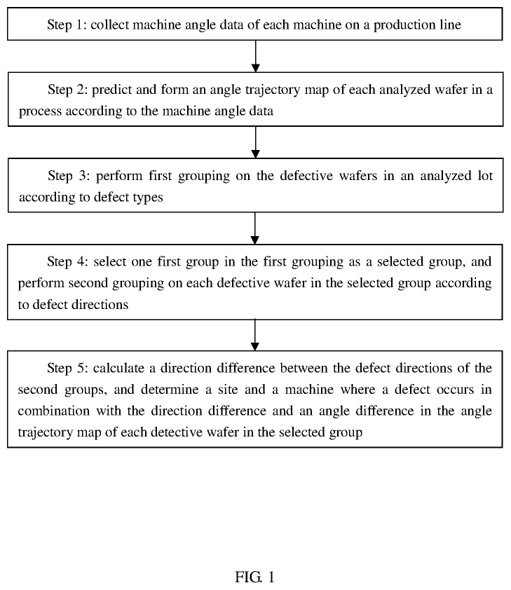

Referring to FIG. 1, it illustrates a flowchart of a method for analyzing a wafer angle in semiconductor integrated circuit manufacturing according to an embodiment of this application. The method for analyzing the wafer angle in semiconductor integrated circuit manufacturing according to this embodiment of this application includes the following steps:

In step 1, machine angle data of each machine on a production line of semiconductor integrated circuits are collected. A machine angle is a wafer angle at which a wafer is processed on the machine.

In the method according to this embodiment of this application, the machine angle data further includes a data type of the machine angle, the data type is defined by a part associated with the machine angle, and the part associated with the machine angle includes wafer loadport, wafer loadlock chamber, airlock chamber, or process chamber.

In some embodiments, in the data type, the part associated with the machine angle further includes recipe, product or process ID.

In the method according to this embodiment of this application, the machine angle data further includes a rule judgment given according to the data type, and the rule judgment given to the same data type is the same.

The machine angle data is automatically collected or manually input.

In some embodiments, the machine angle data may be created as an association information table of machines, angles, data types, and rule judgments. The data is filled in the association information table according to Table 1 below:

TABLE 1

| | | Equipment | Aligned or | Angle | | Angle | |
|---|---|---|---|---|---|---|---|
| Category | Department | ID | not | condition | Angle | description | Flag |
| To be filled | To be filled | To be filled | To be filled | To be filled | To be filled | To be filled | To be filled |

The first row in Table 1 corresponds to the names of various types of data to be filled in the table, while “To be filled” in the second row indicates that specific content needs to be filled in. For example:

“Category” in the first row corresponds to category, i.e., the process category of machine equipment, including process or metrology. In the column corresponding to “Category”, the actual category is filled in according to the actual situation. For example, process or metrology is filled in.

“Department” represents module, i.e., the department to which the machine equipment belongs, such as chemical mechanical Polishing (CMP), etching (ETCH), ion implantation (IMP), chemical vapor deposition (CVD), metal (Metal), wafer acceptance testing (WAT), diffusion (DIFF), yield enhancement (YE), and wet process (WET). Each row in the column corresponding to “Department” may be filled in according to the actual department.

“Equipment ID” represents the ID of the machine on the production line, which may be filled in according to the actual situation.

“Aligned or not” represents whether the corresponding machine ID is aligned, which may be filled in according to the actual situation.

“Angle condition” represents the situation where an angle needs to be set in the corresponding machine, i.e., the part related to the angle, such as layer, airlock, recipe, random, loadlock, loadport, loadport+airlock, lot, process chamber or the like of some products.

“Angle” represents the corresponding angle of the machine, which may be filled in according to the actual situation.

“Angle description” represents the description of the changing rule of the angle, i.e., the description of the rule judgment. For example, in a case that there are two airlocks and “Angle” is 330°, “Angle description” may be filled as follows: airlock1 out 330° and airlock2 out 30°, that is, the angles are different for the same wafer when it is output from airlock1 and airlock2, so that the actual angle of the wafer can be determined based on whether the wafer is output from airlock1 or airlock2. Similarly, when the machine has multiple loadlocks, the corresponding wafer angles are also different when it is input or output from different loadlocks. Similarly, when there are multiple product layers, the angles corresponding to different layers are also different. Therefore, in “Angle description”, it is required to fill in the corresponding wafer angles under various combined conditions according to the actual situation.

“Flag” briefly describes some machine and angle related components. For example, in a case that “Angle condition” and “Angle description” have described the specific layer, the column corresponding to “Flag” only needs to describe the layer. Similarly, in a case that “Angle description” describes various changes in the airlock, “Flag” only needs to describe the airlock.

In the method according to this embodiment of this application, the machine angle data further includes a rule judgment given according to the data type, and the rule judgment given to the same data type is the same.

In step 2, an angle trajectory map of each analyzed wafer in an analyzed lot in a process is predicted and formed according to the machine angle data. The angle trajectory map is a wafer angle distribution map of the analyzed wafer on the machine corresponding to each site in the process.

In the method according to this embodiment of this application, there are usually 25 wafers at most in a lot, and the angle trajectories of the 25 analyzed wafers in a lot may be placed in one table. In the same analyzed lot, most of the process steps experienced by each analyzed wafer are similar. In the table corresponding to the angle trajectory map, the data may be filled in according to step sequence, step description, machine name, i.e., equipment ID, recipe, wafer list, aligned or not, angle description, and predicted angle of each analyzed wafer. The predicted angles of all analyzed wafers formed in each step sequence together form the corresponding angle trajectory map of the analyzed wafers.

In the method according to this embodiment of this application, the angle trajectory map includes the following changes of the wafer angle:
dynamically changing up-down inheritance;
fixed change;
regular angle increase or decrease;
mirrored change;
diagonal change.

That is to say, statistically collecting various changes of the wafer angle into the angle trajectory map can expand the applicability of the wafer angle in the angle trajectory map and make the wafer angle analysis faster and more accurate.

In step 3, defective wafers are made to be the analyzed wafers with defects, and first grouping is performed on the defective wafers in the analyzed lot according to defect types. The defective wafers with the same defect type are classified into the same first group in the first grouping.

In the method according to this embodiment of this application, the defects on the defective wafers are obtained through test equipment.

In step 4, one first group in the first grouping is selected as a selected group, and second grouping is performed on each defective wafer in the selected group according to defect directions. The defective wafers with the same defect direction in the selected group are classified into the same second group in the second grouping.

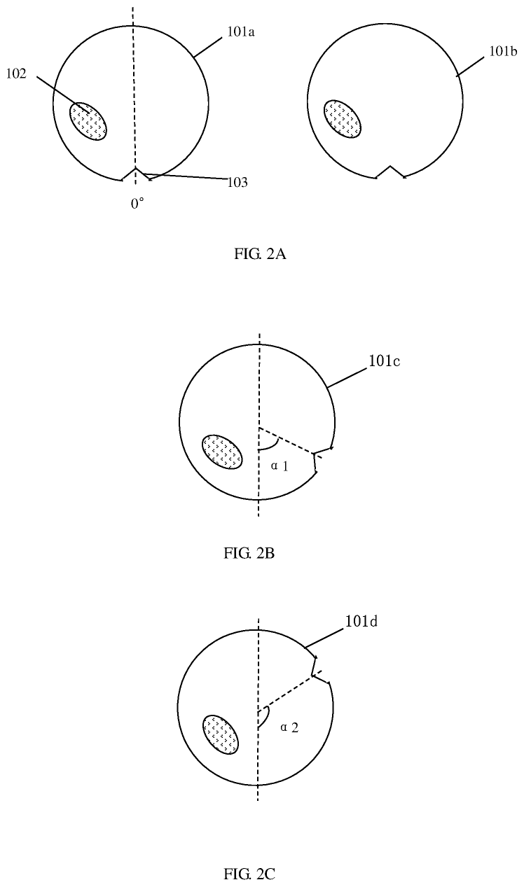

Referring to FIG. 2A to FIG. 2C, they illustrate schematic diagrams of defect directions of second groups in second grouping in the method for analyzing the wafer angle in semiconductor integrated circuit manufacturing according to this embodiment of this application. FIG. 2A to FIG. 2C totally illustrate 4 defective wafers, which are respectively marked as 101a, 101b, 101c, and 101d. It can be seen that the 4 defective wafers all have the same defect corresponding to reference sign 102, and the 4 defective wafers are obtained through the first grouping.

In the second grouping, the defective wafers 101a and 101b in FIG. 2A are further classified into the same group, the defective wafer 101c in FIG. 2B is classified into a group, and the defective wafer 101d illustrated in FIG. 2C is classified into a group.

In step 5, a direction difference between the defect directions of the second groups is calculated.

By comparing FIG. 2A and FIG. 2B, it can be seen that during the comparison, a notch 103 in the defective wafers 101a and 101b is used as a reference, and a direction difference between the defect direction in FIG. 2B and the defect direction in FIG. 2A is angle α1. A direction difference between the defect direction in FIG. 2C and the defect direction in FIG. 2A is angle α2.

The site and the machine where the defect on each defective wafer in the selected group occurs are determined in combination with the direction difference and an angle difference in the angle trajectory map of each detective wafer in the selected group. Usually, a site corresponds to the implementation of a process, and a site includes more than one machine, each of which can implement the process of the site. However, in the actual process, after a lot of wafers enter the corresponding site, they usually enter the selected machine simultaneously to achieve the corresponding process. In a case that the machine has a problem that causes defects on the wafers, the relative position of the defects inside the machine is fixed, but the wafer angles of the wafers inside the machine may be different. Therefore, there may be a situation that the defect type is the same, but the defect directions are different. The angle trajectory map can display the wafer angle of each defective wafer at each site and on the corresponding machine within each site. By comparing the angle difference between the wafer angles and the direction difference between the defect directions, the corresponding machine can be determined.

In the method according to this embodiment of this application, in step 3, in a case that the number of the first group is more than two, step 4 and step 5 are repeated to sequentially determine the site and the machine where the defect corresponding to each first group occurs.

In this embodiment of this application, machine angle data of each machine on a production line is collected in advance, then an angle trajectory of each corresponding analyzed wafer is predicted based on the machine angle data, then first grouping is performed on defective wafers according to defect types, second grouping is performed on one selected first group with the same defect type to obtain second groups, a direction difference between the defect directions of the second groups is determined, the wafer angle of the defective wafer in each second group at the time that the defect occurs can be analyzed and obtained in combination with the direction difference and an angle difference obtained from the predicted angle trajectory map, and the site and the machine where the defect occurs can be determined according to the wafer angle. Therefore, the wafer angle analysis in this embodiment of this application can be automatically realized without requiring for manual analysis, thus greatly improving analysis efficiency and accuracy, and reducing manpower and time consumption.

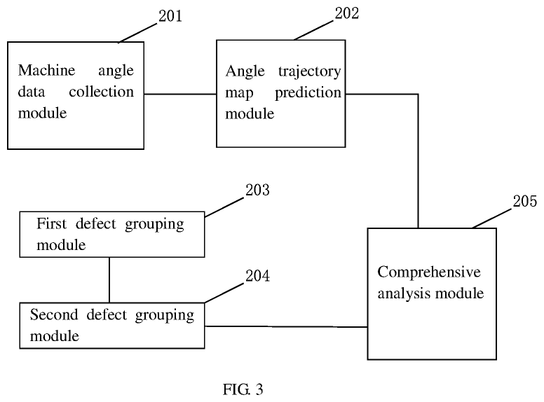

Referring to FIG. 3, it illustrates a structural schematic diagram of a system for analyzing a wafer angle in semiconductor integrated circuit manufacturing according to an embodiment of this application. The system for analyzing the wafer angle in semiconductor integrated circuit manufacturing according to this embodiment of this application includes a machine angle data collection module 201, an angle trajectory map prediction module 202, a first defect grouping module 203, a second defect grouping module 204, and a comprehensive analysis module 205.

The machine angle data collection module 201 is configured to collect machine angle data of each machine on a production line of semiconductor integrated circuits. A machine angle is a wafer angle at which a wafer is processed on the machine.

In this embodiment of this application, the machine angle data further includes a data type of the machine angle, the data type is defined by a part associated with the machine angle, and the part associated with the machine angle includes wafer loadport, wafer loadlock chamber, airlock chamber, or process chamber.

In the data type, the part associated with the machine angle further includes recipe, product or process ID.

The machine angle data further includes a rule judgment given according to the data type, and the rule judgment given to the same data type is the same.

The machine angle data is automatically collected or manually input.

The angle trajectory map prediction module 202 is configured to predict and form an angle trajectory map of each analyzed wafer in an analyzed lot in a process according to the machine angle data. The angle trajectory map is a wafer angle distribution map of the analyzed wafer on the machine corresponding to each site in the process.

The angle trajectory map includes the following changes of the wafer angle:
dynamically changing up-down inheritance;
fixed change;
regular angle increase or decrease;
mirrored change;
diagonal change.

The first defect grouping module 203 is configured to make defective wafers be the analyzed wafers with defects, and perform first grouping on the defective wafers in the analyzed lot according to defect types. The defective wafers with the same defect type are classified into the same first group in the first grouping.

In this embodiment of this application, the defects on the defective wafers are obtained through test equipment.

The second defect grouping module 204 is configured to select one first group in the first grouping as a selected group, and perform second grouping on each defective wafer in the selected group according to defect directions. The defective wafers with the same defect direction in the selected group are classified into the same second group in the second grouping.

The comprehensive analysis module 205 is configured to calculate a direction difference between the defect directions of the second groups, and determine the site and the machine where the defect on each defective wafer in the selected group occurs in combination with the direction difference and an angle difference in the angle trajectory map of each detective wafer in the selected group.

The system for analyzing the wafer angle in semiconductor integrated circuit manufacturing according to this embodiment of this application has been experimentally verified that it can provide defect directions for products in multiple lots, and there is no false alarm rate. In terms of manpower and time consumption, a single person manually takes more than 40 minutes, while the system only takes 1 minute, thus improving efficiency by 40 times.

This application has been described in detail above through specific embodiments, which, however, do not constitute limitations to this application. Without departing from the principles of this application, those skilled in the art may make many modifications and improvements, which should also be considered as included in the scope of protection of this application.

What is claimed is:

1. A method for analyzing a wafer angle in semiconductor integrated circuit manufacturing, comprising the following steps:
step 1: collecting machine angle data of each machine on a production line of semiconductor integrated circuits, a machine angle being a wafer angle at which a wafer is processed on the machine;
step 2: predicting and forming an angle trajectory map of each analyzed wafer in an analyzed lot in a process according to the machine angle data, the angle trajectory map being a wafer angle distribution map of the analyzed wafer on the machine corresponding to each site in the process;
step 3: making defective wafers be the analyzed wafers with defects, and performing first grouping on the defective wafers in the analyzed lot according to defect types, the defective wafers with a same defect type being classified into a same first group in the first grouping;
step 4: selecting one first group in the first grouping as a selected group, and performing second grouping on each defective wafer in the selected group according to defect directions, the defective wafers with a same defect direction in the selected group being classified into a same second group in the second grouping; and
step 5: calculating a direction difference between the defect directions of the second groups, and determining the site and the machine where the defect on each defective wafer in the selected group occurs in combination with the direction difference and an angle difference in the angle trajectory map of each detective wafer in the selected group.

2. The method for analyzing the wafer angle in semiconductor integrated circuit manufacturing according to claim 1, wherein, in step 1, the machine angle data further comprises a data type of the machine angle, the data type is defined by a part associated with the machine angle, and the part associated with the machine angle comprises wafer loadport, wafer loadlock chamber, airlock chamber, or process chamber.

3. The method for analyzing the wafer angle in semiconductor integrated circuit manufacturing according to claim 2, wherein, in the data type, the part associated with the machine angle further comprises recipe, product, or process ID.

4. The method for analyzing the wafer angle in semiconductor integrated circuit manufacturing according to claim 3, wherein the machine angle data further comprises a rule judgment given according to the data type, and the rule judgment given to a same data type is the same.

5. The method for analyzing the wafer angle in semiconductor integrated circuit manufacturing according to claim 3, wherein, in step 1, the machine angle data is automatically collected or manually input.

6. The method for analyzing the wafer angle in semiconductor integrated circuit manufacturing according to claim 1, wherein the defects on the defective wafers are obtained through test equipment.

7. The method for analyzing the wafer angle in semiconductor integrated circuit manufacturing according to claim 1, wherein, in step 3, in a case that a number of the first group is more than two, step 4 and step 5 are repeated to sequentially determine the site and the machine where the defect corresponding to each first group occurs.

8. The method for analyzing the wafer angle in semiconductor integrated circuit manufacturing according to claim 1, wherein, in step 2, the angle trajectory map comprises the following changes of the wafer angle:
dynamically changing up-down inheritance;
fixed change;
regular angle increase or decrease;
mirrored change; and
diagonal change.

9. A system for analyzing a wafer angle in semiconductor integrated circuit manufacturing, comprising:
a machine angle data collection module configured to collect machine angle data of each machine on a production line of semiconductor integrated circuits, a machine angle being a wafer angle at which a wafer is processed on the machine;
an angle trajectory map prediction module configured to predict and form an angle trajectory map of each analyzed wafer in an analyzed lot in a process according to the machine angle data, the angle trajectory map being a wafer angle distribution map of the analyzed wafer on the machine corresponding to each site in the process;
a first defect grouping module configured to make defective wafers be the analyzed wafers with defects, and perform first grouping on the defective wafers in the analyzed lot according to defect types, the defective wafers with a same defect type being classified into a same first group in the first grouping;
a second defect grouping module configured to select one first group in the first grouping as a selected group, and perform second grouping on each defective wafer in the selected group according to defect directions, the defective wafers with a same defect direction in the selected group being classified into a same second group in the second grouping; and
a comprehensive analysis module configured to calculate a direction difference between the defect directions of the second groups, and determine the site and the machine where the defect on each defective wafer in the selected group occurs in combination with the direction difference and an angle difference in the angle trajectory map of each detective wafer in the selected group.

10. The system for analyzing the wafer angle in semiconductor integrated circuit manufacturing according to claim 9, wherein the machine angle data further comprises a data type of the machine angle, the data type is defined by a part associated with the machine angle, and the part associated with the machine angle comprises wafer loadport, wafer loadlock chamber, airlock chamber, or process chamber.

11. The system for analyzing the wafer angle in semiconductor integrated circuit manufacturing according to claim 10, wherein, in the data type, the part associated with the machine angle further comprises recipe, product, or process ID.

12. The system for analyzing the wafer angle in semiconductor integrated circuit manufacturing according to claim 11, wherein the machine angle data further comprises a rule judgment given according to the data type, and the rule judgment given to a same data type is the same.

13. The system for analyzing the wafer angle in semiconductor integrated circuit manufacturing according to claim 11, wherein the machine angle data is automatically collected or manually input.

14. The system for analyzing the wafer angle in semiconductor integrated circuit manufacturing according to claim 9, wherein the defects on the defective wafers are obtained through test equipment.

15. The system for analyzing the wafer angle in semiconductor integrated circuit manufacturing according to claim 9, wherein the angle trajectory map comprises the following changes of the wafer angle:
dynamically changing up-down inheritance;
fixed change;
regular angle increase or decrease;
mirrored change; and
diagonal change.
